(19) United States
(12) Patent Application Publication
(10) Pub. No.: US 2025/0307514 A1
(43) Pub. Date: Oct. 2, 2025

(54) INTEGRATED CIRCUIT DESIGN USING AREA RATIOS

(71) Applicant: Siemens Industry Software Inc., Plano, TX (US)

(72) Inventor: Derong Yan, LAKE OSWEGO, OR (US)

(73) Assignee: Siemens Industry Software Inc., Plano, TX (US)

(21) Appl. No.: 18/624,831

(22) Filed: Apr. 2, 2024

(51) Int. Cl. G06F 30/392

(52) U.S. Cl. CPC G06F 30/392

(57) ABSTRACT

Methods for performing calculations on an integrated circuit (IC) layout design and corresponding systems and computer-readable mediums. A method includes receiving an IC layout design that includes a plurality of circuit elements. The method includes assigning a connection in a same IC net between at least two circuit elements of the plurality of circuit elements and assigning a property value to the at least two circuit elements based on the assigned connection. The method includes performing a calculation, such as a net area ratio calculation, on the IC layout design according to the assigned connections and the assigned property values.

### TECHNICAL FIELD

The present disclosure is directed, in general, to integrated circuit design, with particular application to antenna design rule verification of integrated circuit design.

### BACKGROUND OF THE DISCLOSURE

Modern wafer processing uses “plasma etch” (or “dry etch”) using an ionized/reactive gas. This allows fine control of pattern and also allows a number of chemical reactions that are not possible in traditional (wet) etch.

However, plasma etching may introduce several unwanted effects. One of these is the charging damage, which refers to the unintended high-field stressing of the gate-oxide in MOSFET during plasma processing. The stress voltage that develops across the gate and substrate of a MOSFET during plasma processing can arise from a number of sources, including non-uniform distribution of plasma potential across the wafer, charging filtering (shading) due to microscopic topography on the wafer, or AC effects due to the nature of RF discharge that sustain the plasma.

The stress voltages due to AC effects are quite small in most cases and cannot cause damage by themselves. They do, however, add to the magnitude of stress voltages developed by either non-uniform plasma potential or topographic filtering of charge or the sum of both. The available charges are the net charges collected from the plasma by the exposed conductor with connection to the gate or substrate. Both electrons and positive ions from the plasma are impinging on the exposed conductor during processing. Depending on the charge balance condition, the electron flux might not equal the ion flux, a net positive or negative charge collection rate exists.

One issue in plasma etching is the so called “antenna effect”. The area ratio of the conductor to the oxide under the gate is the antenna ratio. The antenna ratio, in a rough sense, is a current multiplier that amplifies the tunneling current density across the gate-oxide. For a given antenna ratio, a larger tunneling current is supported when the plasma density is higher. Higher tunneling current means higher damage.

However, in current systems, measuring and accommodating the antenna ratios can be difficult or impossible in many cases. Improved systems are desirable.

### SUMMARY OF THE DISCLOSURE

Various disclosed embodiments include methods for performing calculations on an integrated circuit (IC) layout design and corresponding systems and computer-readable mediums. A method includes receiving an IC layout design that includes a plurality of circuit elements. The method includes assigning a connection in a same IC net between at least two circuit elements of the plurality of circuit elements and assigning a property value to at least two circuit elements of the plurality of circuit elements. The assigning of connections and property values may be done incrementally and can happen multiple times as needed. The method includes performing a calculation, such as a net area ratio calculation, on the IC layout design according to the assigned connections and the assigned property values.

Various embodiments also include outputting the result of the calculation and can include modifying the IC layout design according to the result of the calculation. In various embodiments, the plurality of circuit elements are represented by polygons. In various embodiments, each property value is stored as a property of the circuit element to which the property value is assigned. In various embodiments, the connection is assigned based on receiving a command from a user to assign the connection. In various embodiments, the calculation is performed between two or more sets of connected circuit elements. In various embodiments, the connection is assigned based on receiving a command from a user to assign the connection. In various embodiments, the property or the property value is assigned by the system based on receiving a command from a user to assign the property or the property value.

Various embodiments include a computer system having at least one processor and an accessible memory, configured to perform processes described herein. Various embodiments include a non-transitory computer-readable medium encoded with executable instructions that, when executed, cause one or more computer systems to perform processes as described herein.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIGS. 1 and 2 illustrate aspects of a computer system that can be used to implement various embodiments disclosed herein;

FIG. 3 illustrates an example of net area ratio calculations with respect to a PID design rule;

FIG. 4 illustrates an example of using connectivity and property value assignments to perform calculations on a circuit design in accordance with disclosed embodiments; and

FIG. 5 illustrates a flowchart of a process in accordance with disclosed embodiments.

### DETAILED DESCRIPTION

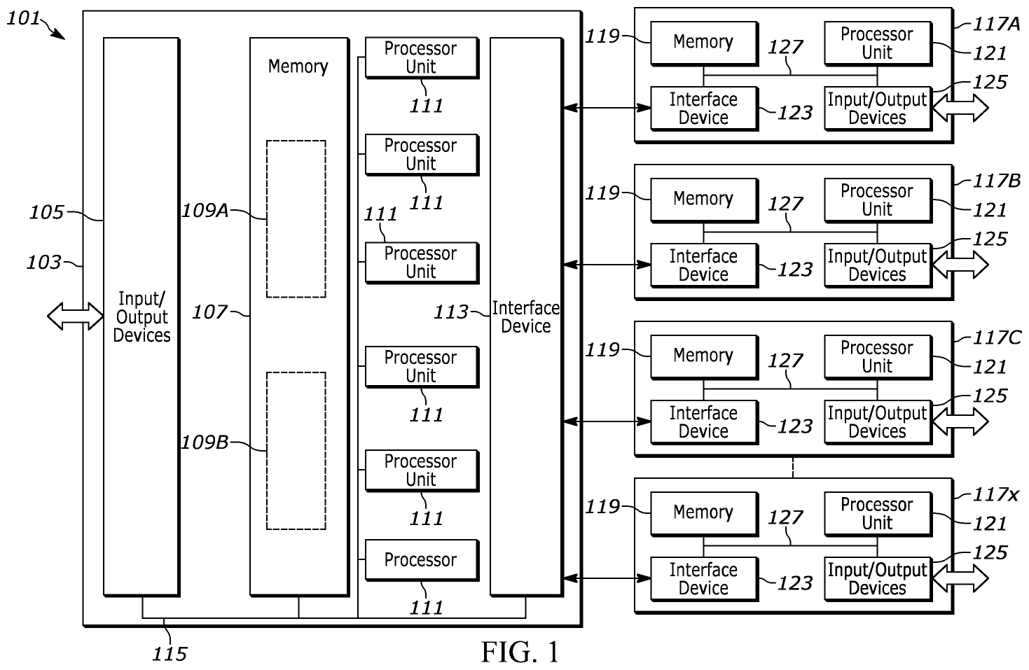

FIGS. 1 through 5, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Disclosed embodiments include systems and methods for calculating area ratios between multiple drawn layers which are not connected to the same nets in an integrated circuit layout design.

When checking antenna design rules on integrated circuit layout designs, area ratios between two or more drawn layers are calculated using Electronic Design Automation (EDA) tools, such as the CALIBRE software of Siemens Digital Industries Software. In the CALIBRE software, for example, a command called NET AREA RATIO is often used, which requires the layer polygons used in the same area ratio calculation to be connected to the same net. Other software tools use a similar function.

As on-chip antennas develop, new antenna design rules include polygons in the same chip layer that are not connected to the same net. Conventional tools cannot include disconnected polygons or disconnected sets of polygons in an area-ratio calculation.

Disclosed embodiments include systems and methods that overcome the technical deficiencies of current systems and enable area ratio calculation to be performed on layer polygons which are not connected to the same net.

### Illustrative Operating Environment

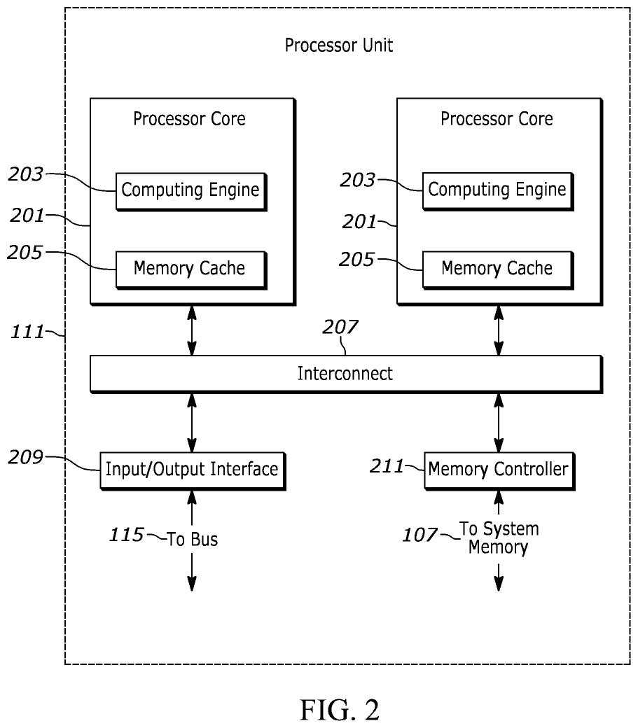

FIGS. 1 and 2 illustrate aspects of a computer system that can be used to implement various embodiments disclosed herein. The execution of various processes described herein may be implemented using computer-executable software instructions executed by one or more programmable computing devices. Because these processes may be implemented using software instructions, the components and operation of a generic programmable computer system on which various embodiments of these processes may be employed will first be described. Further, because of the complexity of some electronic design and testing processes and the large size of many circuit designs, various electronic design and testing tools are configured to operate on a computing system capable of simultaneously running multiple processing threads. The components and operation of a computer system having a host or master computer and one or more remote or slave computers therefore will be described with reference to FIG. 1. This operating environment is only one example of a suitable operating environment, however, and is not intended to suggest any limitation as to the scope of use or functionality of any implementations of the invention.

In FIG. 1, the computer system 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other non-transitory storage medium that can be used to store desired information. As used herein, the term “non-transitory” refers to the ability to store information for subsequent retrieval at a desired time, as opposed to propagating electromagnetic signals.

As will be discussed in detail below, the master computer 103 runs a software application for performing one or more operations according to various examples of the invention. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

With some implementations of the invention, the master computer 103 may employ one or more processing units 111 having more than one processor core. Accordingly, FIG. 2 illustrates an example of a multi-core processor unit 111 that may be employed with various embodiments of the invention. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 201. With some processor cores 201, such as the Cell microprocessor created by Sony Corporation, Toshiba Corporation and IBM Corporation, the interconnect 207 may be implemented as an interconnect bus. With other processor units 201, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interfaces 209 and a memory controller 211. The input/output interface 209 provides a communication interface between the processor unit 201 and the bus 115. Similarly, the memory controller 211 controls the exchange of information between the processor unit 201 and the system memory 107. With some implementations of the invention, the processor units 201 may include additional components, such as a high-level cache memory accessible shared by the processor cores 201.

While FIG. 2 shows one illustration of a processor unit 201 that may be employed by some embodiments of the invention, it should be appreciated that this illustration is representative only and is not intended to be limiting. It also should be appreciated that, with some implementations, a multi-core processor unit 111 can be used in lieu of multiple, separate processor units 111. For example, rather than employing six separate processor units 111, an alternate implementation of the computing system 101 may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the slave computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the slave computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each slave computer 117 may include a memory 119, a processor unit 121, an interface device 123, and, optionally, one more input/output devices 125 connected together by a system bus 127. As with the master computer 103, the optional input/output devices 125 for the slave computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. The memory 119 then may be implemented using any combination of the computer readable media discussed above. Like the interface device 113, the interface devices 123 allow the slave computers 117 to communicate with the master computer 103 over the communication interface.

In the illustrated example, the master computer 103 is a multi-processor unit computer with multiple processor units 111, while each slave computer 117 has a single processor unit 121. It should be noted, however, that alternate implementations of the technology may employ a master computer having single processor unit 111. Further, one or more of the slave computers 117 may have multiple processor units 121, depending upon their intended use, as previously discussed. Also, while only a single interface device 113 or 123 is illustrated for both the master computer 103 and the slave computers, it should be noted that, with alternate embodiments of the invention, either the computer 103, one or more of the slave computers 117, or some combination of both may use two or more different interface devices 113 or 123 for communicating over multiple communication interfaces.

With various examples of the computer system 101, the master computer 103 may be connected to one or more external data storage devices. These external data storage devices may be implemented using any combination of non-transitory computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the computer system 101, one or more of the slave computers 117 may alternately or additions be connected to one or more external non-transitory data storage devices. Typically, these external non-transitory data storage devices will include data storage devices that also are connected to the master computer 103, but they also may be different from any data storage devices accessible by the master computer 103.

It also should be appreciated that the description of the computer system 101 illustrated in FIG. 1 and FIG. 2 is provided as an example only, and is not intended to suggest any limitation as to the scope of use or functionality of various embodiments of the invention.

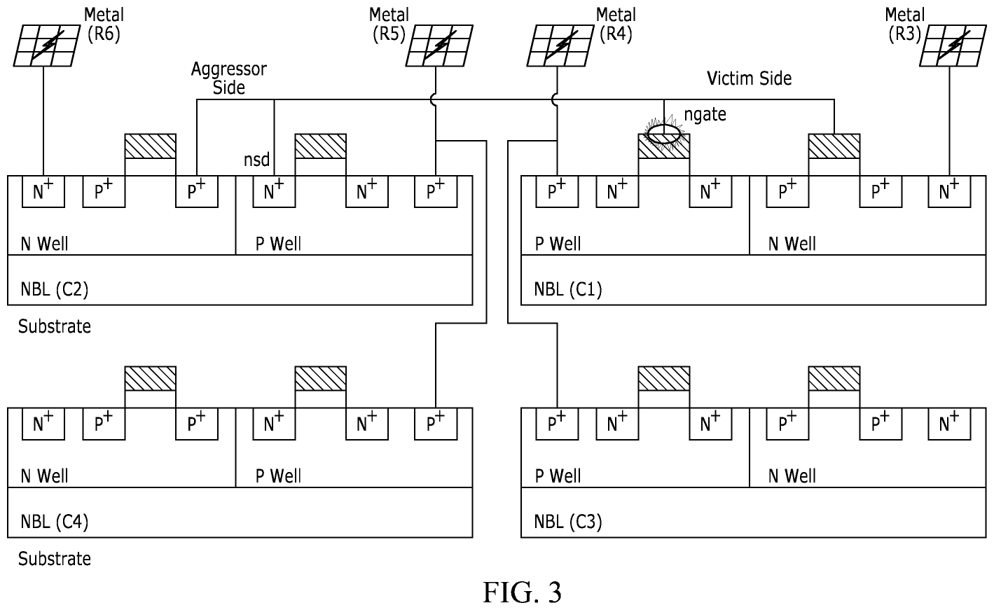

FIG. 3 illustrates an example of net area ratio calculations with respect to a PID design rule. When checking such antenna design rules, commands which are built for calculating area ratios, e.g., NET AREA RATIO, cannot be utilized directly. In current systems, the system assigns polygon properties to layer polygons and uses these properties to keep track of the connectivity and area of each polygon. Then such a system uses primitive rule deck commands (instead of powerful command specific to net area ratio calculations, such as NET AREA RATIO) to do arithmetic calculation to add up the areas of polygons that belong to the same layer and that are associated with the same area ratio calculation, and then it calculates area ratios between different layers. Since command such as NET AREA RATIO is not used due to the fact that layer polygons used in the same area ratio calculation are not connected to the same net, in prior art it has to use more primitive rule deck commands to count the polygons and do area ratio calculations. Therefore, the rule decks are cumbersome and difficult to read and maintain.

For example, in the context of FIG. 3, R represents a metal or via area (single layer), and C represents the area of an N buried Layer (NBL). R3-R6 therefore represent the areas of a metal or via layer and C1-C4 represent the areas of NBL layer. An exemplary area-ratio calculation would therefore be

$$( R 3 + R 4 ) / ( C 1 + C 3 ) and$$

$$( R 5 + R 6 ) / ( C 2 + C 4 )$$

but R3 and R4 are not connected, C1 and C3 are not connected, R5 and R6 are not connected, and C2 and C4 are not connected. Because they are not, a cumbersome and iterative manual calculation must be performed in current systems in order to compute these area ratios. The approach required in previous systems requires rule deck commands which are cumbersome and difficult to read and maintain.

Disclosed embodiments improve open known techniques. As described herein, the system can use functions such as CONNECT statements to connect layer polygons based on their functions in layout design and based on PID design rule. The layer polygons which receive the connection assignments include both the layer polygons which will be directly used in area ratio calculations and the layer polygons which will not be directly used in area ratio calculations but need to be included to complete the connections.

The system can then assign a polygon property (or other parameter) to the layer polygons based on the assigned connections. Layer polygons which receive the assignment of polygon property include both the layer polygons which will be directly used in area ratio calculations and the layer polygons which will not be directly used in area ratio calculations but need to be included as part of the assigning of property values.

Property values can then be assigned to layer polygons using Calibre DFM Property statements or similar commands. When using DFM Property statements or similar commands to assign property values, the property values are propagated through layer polygons based on assigned connections and/or direct physical overlaps.

To ensure that desired property values are assigned to and are only assigned to desired layer polygons, the assignments of connections and property values may be performed incrementally and may iterate multiple times.

After assigning property values, the system can treat the polygons with the same connectivity assignment in the property values as connected within the layer. In some implementations, for example, the system can apply additional CONNECT statements based on the connectivity assignments to connect the layer polygons that are to be treated as connected and used in the same area ratio calculation.

The layer polygons used in the same area ratio calculation can be selected, for example, based on the design rules and circuit connectivity and are assigned a value, tag, or other indicator as a property or parameter (generically referred to herein as a property value) that indicates a connectivity assignment that is independent of the connectivity that may be represented in the current layout design. For example, in the context of FIG. 3, R3 and R4 can be assigned a property value that indicates they have the same connectivity assignment, so that, using the connectivity assignment, the system can treat R3 and R4 as connected in area ratio calculations (and for other functions) even if no current physical connection is indicated in the layout design.

After the appropriate polygons are designated as “connected” in this way, the system can thereafter perform a circuit design function according to the designated connectivity. As one example, the system can perform a function to calculate the net area ratio, such as the Calibre NET AREA RATIO command. The system performs the circuit design function using layer polygons which are not only connected to the same net but also have the same connectivity assignment.

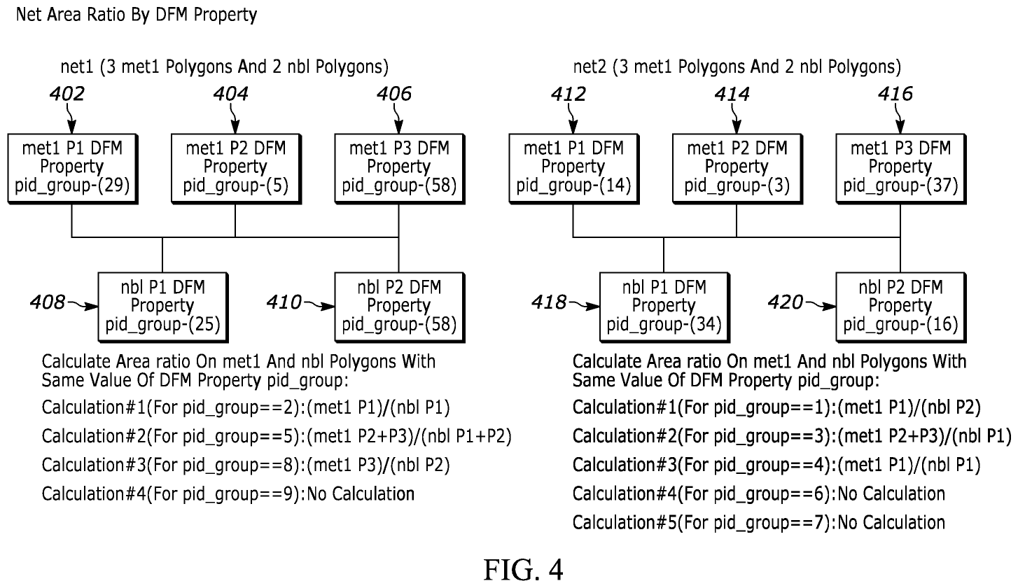

FIG. 4 illustrates an example of using connectivity assignments to perform calculations on a circuit design, and specifically for performing net area ratio calculations using design for manufacturing (DFM) properties for the connectivity assignment. In this example, the DFM property pid_group is used to store one or more connectivity assignments.

In this example, polygon 402 is a metal polygon (on metal 1, which is abbreviated as met1) that has a pid_group property with the connectivity assignments 2 and 9. Polygon 404 is a metal polygon that has a pid_group property with the connectivity assignment 5. Polygon 406 is a metal polygon that has a pid_group property with the connectivity assignments 5 and 8. Polygon 408 is an NBL polygon (nbl) that has a pid_group property with the connectivity assignments 2 and 5. Polygon 410 is an NBL polygon that has a pid_group property with the connectivity assignments 5 and 8.

Among these, the system can consider 402 and 408 to be connected based on connectivity assignment 2, can consider 404, 406, 408, and 410 to be connected based on connectivity assignment 5, and can consider 406 and 410 to be connected (without 404 and 408) based on connectivity assignment 8. Using these connections, the system can calculate area ratios as illustrated in FIG. 4.

Similarly, in this example, polygon 412 is a metal polygon that has a pid_group property with the connectivity assignments 1 and 4. Polygon 414 is a metal polygon that has a pid_group property with the connectivity assignment 3. Polygon 416 is a metal polygon that has a pid_group property with the connectivity assignments 3 and 7. Polygon 418 is an NBL polygon that has a pid_group property with the connectivity assignments 3 and 4. Polygon 420 is an NBL polygon that has a pid_group property with the connectivity assignments 1 and 6.

Among these, the system can consider 412 and 418 to be connected based on connectivity assignment 4, can consider 412 and 420 to be connected based on connectivity assignment 1, and can consider 414, 416, and 418 to be connected based on connectivity assignment 3. Using these connections, the system can calculate area ratios as illustrated in FIG. 4.

While this example uses a DFM property pid_group with single-digit connectivity assignments, other embodiments can use any property or parameter that can be assigned to a polygon.

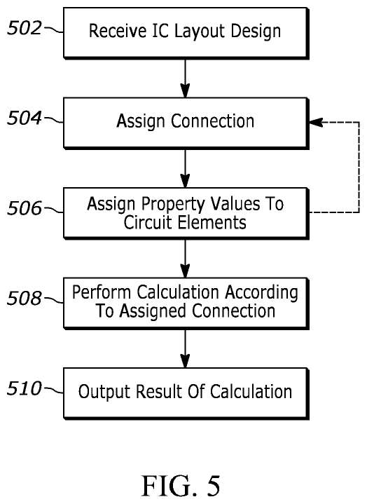

FIG. 5 depicts a flowchart of a process in accordance with disclosed embodiments that may be performed, for example, by one or more computer systems 101 as disclosed herein (generically referred to as the “system” below).

At 502, the system receives an integrated circuit (IC) layout design including plurality of circuit elements. The IC layout design can be in any known format, and particularly can be in a format usable by EDA tools. The circuit elements can be any type of IC elements, and can be represented by polygons. “Receiving,” as used herein, can include loading from storage, receiving from another device or process, receiving via an interaction with a user, or otherwise.

At 504, the system assigns a connection in the same IC net between at least two circuit elements of the plurality of circuit elements, which can be based on their functions in circuit design and/or based on the PID design rule. This can be performed manually, such as by receiving a CONNECT command from a user that indicates that at least two circuit elements should be connected in the same IC net.

At 506, the system assigns a property value to each of the at least two circuit elements, with the property value indicating a connectivity assignment between the at least two circuit elements. In this step, each of the circuit elements can be assigned one or more property values, and corresponding property values of different circuit elements can indicate the connectivity assignment between those circuit elements. “Corresponding” property values can be equal property values, as in the example of FIG. 4, or can be corresponding in some other way, such as designating that property values of within certain range are considered to be corresponding and to indicate a connectivity assignment. The property value can be stored as any property or parameter of each circuit element, and can in particular be stored in a DFM property pid_group as disclosed herein. In some implementations, the property or the property value is assigned by the system based on receiving a command from a user to assign the property or the property value.

To ensure that desired property values are assigned to and are only assigned to desired layer polygons, the assignment of connections in 504 and the assignment of property values in 506 may be performed incrementally and may iterate multiple times.

At 508, the system performs a calculation on the IC layout design according to the assigned connection and property value between the at least two circuit elements. This can include, in particular, performing a net area ratio calculation according to the assigned connection and property value.

At 510, the system outputs a result of the calculation, which can include storing the result, displaying the result to a user, and/or transmitting the result to another device or process.

Note that the process of FIG. 5 is described in terms of assigning at least two circuit elements to be connected in a net, but in an actual implementation, there may be many sets of circuit elements assigned to be connected in different nets, other circuit elements that may not be assigned to be connected (based on the property value) to any other element, circuit elements that may be assigned as connected (based on the property value) to various different other circuit elements depending on the context or application, and circuit elements that may be actually connected in the layout design but may or may not be assigned to be connected based on the property value. The calculation can be performed between two or more sets of connected circuit elements.

The system can thereafter modify the circuit layout based on the result, and can manufacture a physical integrated circuit based on the circuit layout.

Of course, those skilled in the art will recognize that, unless specifically indicated or required by the sequence of operations, certain steps in the processes described above may be omitted, performed concurrently or sequentially, or performed in a different order.

Those skilled in the art will recognize that, for simplicity and clarity, the full structure and operation of all computer systems suitable for use with the present disclosure is not being depicted or described herein. Instead, only so much of a computer system as is unique to the present disclosure or necessary for an understanding of the present disclosure is depicted and described. The remainder of the construction and operation of computer system 101 may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims. Moreover, none of these claims are intended to invoke 35 USC § 112(f) unless the exact words “means for” are followed by a participle. The use of terms such as (but not limited to) “mechanism,” “module,” “device,” “unit,” “component,” “element,” “member,” “apparatus,” “machine,” “system,” “processor,” or “controller,” within a claim is understood and intended to refer to structures known to those skilled in the relevant art, as further modified or enhanced by the features of the claims themselves, and is not intended to invoke 35 U.S.C. § 112(f).

What is claimed is:

1. A method performed by a computer system and comprising:
receiving an integrated circuit (IC) layout design including a plurality of circuit elements;
assigning a connection in a same IC net between at least two circuit elements of the plurality of circuit elements;
assigning a property value to each of the at least two circuit elements based on the assigned connection; and
performing a calculation on the IC layout design according to the assigned connection and the assigned property values.

2. The method of claim 1, wherein the calculation is a net area ratio calculation.

3. The method of claim 1, further comprising outputting the result of the calculation.

4. The method of claim 1, wherein the plurality of circuit elements are represented by polygons.

5. The method of claim 1, wherein each property value is stored as a property of the circuit element to which the property value is assigned.

6. The method of claim 1, wherein the connection is assigned based on receiving a command from a user to assign the connection.

7. The method of claim 1, wherein the property or the property value is assigned based on receiving a command from a user to assign the property or the property value.

8. The method of claim 1, wherein the calculation is performed between two or more sets of connected circuit elements.

9. A computer system comprising at least one processor and an accessible memory, the computer system particularly configured to:
receive an integrated circuit (IC) layout design including a plurality of circuit elements;
assign a connection in a same IC net between at least two circuit elements of the plurality of circuit elements;
assign a property value to each of the at least two circuit elements based on the assigned connection; and
perform a calculation on the IC layout design according to the assigned connection and the assigned property values.

10. The computer system of claim 9, wherein the calculation is a net area ratio calculation.

11. The computer system of claim 9, wherein the computer system is further configured to output the result of the calculation.

12. The computer system of claim 9, wherein the plurality of circuit elements are represented by polygons.

13. The computer system of claim 9, wherein each property value is stored as a property of the circuit element to which the property value is assigned.

14. The computer system of claim 9, wherein the connection is assigned based on receiving a command from a user to assign the connection.

15. The computer system of claim 9, wherein the property or the property value is assigned based on receiving a command from a user to assign the property or the property value.

16. The computer system of claim 9, wherein the calculation is performed between two or more sets of connected circuit elements.

17. A non-transitory computer-readable medium encoded with executable instructions that, when executed, cause one or more computer systems to:
receive an integrated circuit (IC) layout design including a plurality of circuit elements;
assign a connection in a same IC net between at least two circuit elements of the plurality of circuit elements;
assign a property value to each of the at least two circuit elements based on the assigned connection; and
perform a calculation on the IC layout design according to the assigned connection and the assigned property values.

18. The non-transitory computer-readable medium of claim 17, wherein the calculation is a net area ratio calculation and the executable instructions, when executed, further cause the one or more computer systems to output the result of the calculation.

19. The non-transitory computer-readable medium of claim 17, wherein the connection is assigned based on receiving a command from a user to assign the connection, and wherein the property or the property value is assigned based on receiving a command from a user to assign the property or the property value.

20. The non-transitory computer-readable medium of claim 17, wherein the calculation is performed between two or more sets of connected circuit elements.
